(19) United States
(12) Patent Application Publication
(10) Pub. No.: US 2025/0301893 A1
(43) Pub. Date: Sep. 25, 2025

(54) DISPLAY DEVICE INCLUDING COVER LAYER, ELECTRONIC DEVICES AND COVER LAYER FOR DISPLAY DEVICES

(71) Applicant: Samsung Display Co., LTD., Yongin-si (KR)

(72) Inventors: Sung Woo KIM, Yongin-si (KR); Chae Kyeong LEE, Yongin-si (KR); Seung Kuk KUK, Yongin-si (KR); Jeong Seok LEE, Yongin-si (KR)

(21) Appl. No.: 18/957,313

(22) Filed: Nov. 22, 2024

(30) Foreign Application Priority Data
Mar. 25, 2024 (KR) 10-2024-0040350

(51) Int. Cl. H10K 59/80

(52) U.S. Cl. CPC H10K 59/8791; H10K 59/873

(57) ABSTRACT

Provided herein are a cover layer for display devices: including a window layer; a first cover layer on the window layer; and a second cover layer on the first cover layer. The first cover layer may include silicon oxide (SiOₓ) having a first packing density. The second cover layer may include silicon oxide having a second packing density different from the first packing density. The first cover layer and the second cover layer may be in contact with each other.

### CROSS-REFERENCE TO RELATED APPLICATION

The present application claims priority to and the benefit of Korean patent application number 10-2024-0040350 filed on Mar. 25, 2024, the entire content of which is hereby incorporated in its entirety by reference.

### BACKGROUND

### 1. Field

Various embodiments of the present disclosure relate to a display device including a cover layer, electronic devices and a cover layer for display devices.

### 2. Description of Related Art

With the development of information technology, the importance of display devices as a medium that connects users and information has been emphasized.

At least some display devices utilize a structure that improves external visibility. For example, there is a desire to adjust external light reflectance to improve the external visibility.

### SUMMARY

Various embodiments of the present disclosure are directed to a cover layer for display devices having enhanced visibility by controlling external light reflectance, and a display device including the cover layer.

Various embodiments of the present disclosure are directed to a cover layer for display devices having improved reliability in display quality achieved by excellent reflective color properties, and a display device including the cover layer.

Various embodiments of the present disclosure are directed to a cover layer for display devices capable of reducing the cost of producing a display device, and a display device including the cover layer.

An embodiment of the present disclosure may provide a cover layer for display devices, including: a window layer; a first cover layer on the window layer; and a second cover layer on the first cover layer. The first cover layer may include silicon oxide (SiOₓ) having a first packing density. The second cover layer may include silicon oxide having a second packing density different from the first packing density. The first cover layer and the second cover layer may be in contact with each other.

According to one or more embodiments, the second packing density may be in a range from about 75% to about 95% of the first packing density.

According to one or more embodiments, the silicon oxide may include silicon dioxide (SiO₂).

According to one or more embodiments, the first cover layer may include the silicon dioxide having a planar structure. The second cover layer may include the silicon dioxide having a columnar structure.

According to one or more embodiments, the first cover layer may be formed through a sputtering process. The second cover layer may be formed through an electronic-beam evaporation process.

According to one or more embodiments, the first cover layer may have a first thickness. The second cover layer may have a second thickness. The first thickness may range from about 5 nm to about 15 nm or range from about 0.1 nm to about 9 nm. The second thickness may range from 68 nm to 83 nm or range from about 85 nm to about 100 nm.

According to one or more embodiments, the first cover layer may have a refractive index in a range from 1.43 to 1.52. The second cover layer may have a refractive index in a range from 1.32 to 1.52.

According to one or more embodiments, the cover layer may further include a third cover layer on the second cover layer. The second cover layer and the third cover layer may be in contact with each other.

According to one or more embodiments, the third cover layer may be formed through thermal evaporation and/or electronic-beam evaporation.

According to one or more embodiments, the third cover layer may include perfluorinated polyether (PFPE).

According to one or more embodiments, the third cover layer may have a thickness in a range from about 20 nm to about 30 nm.

An embodiment of the present disclosure may provide a cover layer for display devices, including: a window layer; a first cover layer on the window layer, and having a first packing density and a first thickness; and a second cover layer directly on the first cover layer, and having a second packing density and a second thickness. The first cover layer and the second cover layer may include an identical material. The first packing density and the second packing density may differ from each other. The second thickness may be greater than the first thickness.

According to one or more embodiments, the first cover layer may be formed through a sputtering process. The second cover layer may be formed through an electronic-beam evaporation process.

According to one or more embodiments, the material may include silicon dioxide (SiO₂). The second packing density may be in a range from about 75% to about 95% of the first packing density. The first cover layer may include the silicon dioxide having a planar structure. The second cover layer may include the silicon dioxide having a columnar structure.

According to one or more embodiments, the first cover layer may have a higher refractive index than the second cover layer.

An embodiment of the present disclosure may provide a display device, including: a light-emitting-element layer including a light emitting element configured to emit light; and a cover layer on the light-emitting-element layer. The cover layer may include: a window layer; a first cover layer on the window layer; and a second cover layer on the first cover layer. The first cover layer may include silicon oxide (SiOₓ) having a first packing density. The second cover layer may include silicon oxide having a second packing density different from the first packing density. The first cover layer and the second cover layer may be in contact with each other.

According to one or more embodiments, the first cover layer may be formed through a process different from a process of forming the second cover layer.

According to one or more embodiments, the first cover layer may have a first thickness. The second cover layer may have a second thickness. The first thickness may range from about 5 nm to about 15 nm or range from about 0.1 nm to about 9 nm. The second thickness may range from about 68 nm to about 83 nm or range from about 85 nm to about 100 nm.

According to one or more embodiments, the first cover layer may have a refractive index in a range from about 1.43 to about 1.52. The second cover layer may have a refractive index in a range from about 1.32 to about 1.52.

According to one or more embodiments, the display device may further include a third cover layer on the second cover layer. The second cover layer and the third cover layer may be in contact with each other. The third cover layer may have a thickness in a range from about 20 nm to about 30 nm.

An electronic device includes a processor to provide input image data; and a display device to display an image based on the input image data. The display device includes a light-emitting-element layer comprising a light emitting element configured to emit light; and a cover layer on the light-emitting-element layer. The cover layer includes a window layer; a first cover layer on the window layer; and a second cover layer on the first cover layer. The first cover layer includes silicon oxide (SiOₓ) having a first packing density. The second cover layer includes silicon oxide having a second packing density different from the first packing density, and the first cover layer and the second cover layer are in contact with each other.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a schematic plan view illustrating a display device in accordance with an embodiment.

FIG. 2 is a schematic cross-sectional view illustrating a display device in accordance with an embodiment.

FIG. 3 is a schematic cross-sectional view illustrating a cover layer in accordance with an embodiment.

FIG. 4 is a schematic cross-sectional view of comparative example 1.

FIG. 5 is a schematic block diagram illustrating an electronic device 1000 including a display device in accordance with an embodiment.

FIG. 6 is a schematic diagram illustrating an example where the electronic device 1000 of FIG. 5 is a smartphone.

FIG. 7 is a schematic diagram illustrating an example where the electronic device 1000 of FIG. 5 is a tablet computer.

### DETAILED DESCRIPTION

As the subject matter of the present disclosure allows for various changes and numerous embodiments, example embodiments will be illustrated in the drawings and described in more detail in the written description. However, this is not intended to limit the present disclosure to particular modes of practice, and it is to be appreciated that all changes, equivalents, and substitutes that do not depart from the spirit and technical scope of the present disclosure are encompassed in the present disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the spirit or scope of the present disclosure. Similarly, the second element could also be termed the first element. In the present disclosure, the singular forms are intended to include the plural forms as well, unless the context clearly indicates otherwise.

It will be further understood that the terms “comprise”, “include”, “have”, etc. when used in the present disclosure, specify the presence of stated features, integers, steps, operations, elements, components, and/or combinations of them but do not preclude the presence or addition of one or more other features, integers, acts, operations, elements, components, and/or combinations thereof. Furthermore, in case that a first part such as a layer, a film, a region, or a plate is on a second part, the first part may be not only directly on the second part but a third part may intervene between them. In embodiments, when it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

Various embodiments of the present disclosure relate to a display device including a cover layer, and a cover layer for display devices. Hereinafter, a display device in accordance with an embodiment will be described with reference to the attached drawings.

### 1. Display Device

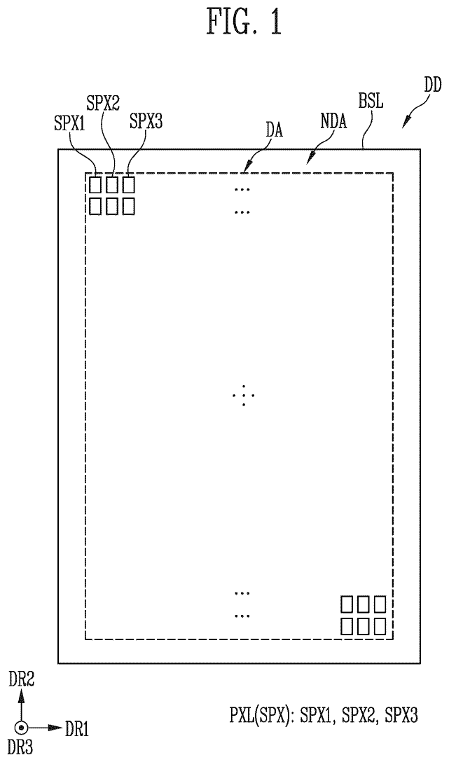

FIG. 1 is a schematic plan view illustrating a display device DD in accordance with an embodiment.

Referring to FIG. 1, the display device DD may include a base layer BSL, and pixels PXL on the base layer BSL. The display device DD may emit light.

According to one or more embodiments, the display device DD may be a device configured to display a video and/or a static image. The display device DD may be used not only as portable electronic devices such as a mobile phone, a smart phone, a tablet personal computer (a table PC), a smart watch, a watch phone, a mobile communication terminal, an electronic notebook, an electronic book, a portable multimedia player (PMP), a navigation device, and/or an ultra mobile PC (UMPC), but also as display screens of various suitable products such as a television, a notebook, a monitor, an advertisement panel, and an internet of things (IOT) device. Here, the application field of the display device DD is not limited to a specific example.

According to one or more embodiments, the display device DD may be formed of a rectangular panel having short sides extending in a first direction DR1, and long sides extending a second direction DR2 intersecting with the first direction DR1. Corners where the short sides extending in the first direction DR1 and the long sides extending in the second direction DR2 meet may be rounded to have a set or certain curvature or may be formed at a right angle. The plane shape of the display device DD is not limited to a rectangular shape, and may have other polygonal shapes, or a rounded shape such as a circular shape (e.g., a generally circular shape) or an elliptical shape. The display device DD may be formed to be planar, but it is not limited thereto. For example, the display device DD may include a curved surface which is formed on each of left and right side edges thereof and has a constant curvature or a suitably varying curvature. In embodiments, the display device DD may be formed to be flexible so that the display device DD can be bent, curved, folded, and/or rolled.

In embodiments of the present disclosure, the first direction DR1 may be a “horizontal” direction in a row direction of the pixel PXL. The second direction DR2 may be a column direction of the pixel PXL. A third direction DR3 may correspond to a display direction of the display device DD or a normal direction of a plane on which the base layer BSL is provided.

According to one or more embodiments, the display device DD may further include a driving circuit component (e.g., a scan driver and a data driver), lines, and pads to drive the pixels PXL.

The display device DD (or the base layer BSL) may include a display area DA and a non-display area NDA. The non-display area NDA may refer to an area other than the display area DA. The non-display area NDA may enclose at least a portion of the display area DA.

The base layer BSL may form a base surface of the display device DD. The base layer BSL may be a rigid or flexible substrate and/or film. For example, the base layer BSL may be a rigid substrate made of glass and/or reinforced glass, a flexible substrate (or a thin film) formed of plastic and/or metal, and/or at least one insulating layer (e.g., at least one electrically insulating layer). The material and/or properties of the base layer BSL are not particularly limited. According to one or more embodiments, the base layer BSL may be substantially transparent. Here, the words “substantially transparent” may mean that light can pass through the base layer BSL with a transmittance (e.g., a light transmittance) of a set or certain value or more. According to one or more embodiments, the base layer BSL may be translucent or opaque. Furthermore, the base layer BSL may include a reflective material (e.g., a light reflective material) depending on the embodiment.

The display area DA may refer to an area in which the pixels PXL are provided. The non-display area NDA may refer to an area in which the pixels PXL are not provided. The driving circuit component, the lines, and the pads which are connected to the pixels PXL of the display area DA may be in the non-display area NDA.

In accordance with an embodiment, the pixels PXL (or the sub-pixels SPX) may be in a stripe or PENTILE™ arrangement structure (e.g., an RGBG matrix, RGBG structure, or RGBG matrix structure) or the like, but the present disclosure is not limited thereto. PENTILE® is a duly registered trademark of Samsung Display Co., Ltd. Various suitable embodiments may be applied to the present disclosure.

In accordance with an embodiment, each pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form a pixel unit which may emit various suitable colors of light.

For example, each of the first sub-pixel SPX1, the second sub-pixel SPX2, and the third sub-pixel SPX3 may emit a single color of light. For instance, the first sub-pixel SPX1 may be a red pixel configured to emit light in red (e.g., a first color), the second sub-pixel SPX2 may be a green pixel configured to emit light in green (e.g., a second color), and the third sub-pixel SPX3 may be a blue pixel configured to emit light in blue (e.g., a third color). In accordance with an embodiment, the number of second sub-pixels SPX2 may be greater than the number of first sub-pixels SPX1, or the number of third sub-pixels SPX3. The colors, types (or kinds), and/or numbers of first sub-pixels SPX1, second sub-pixels SPX2, and the third sub-pixels SPX3 which form each pixel unit are not limited to a specific example.

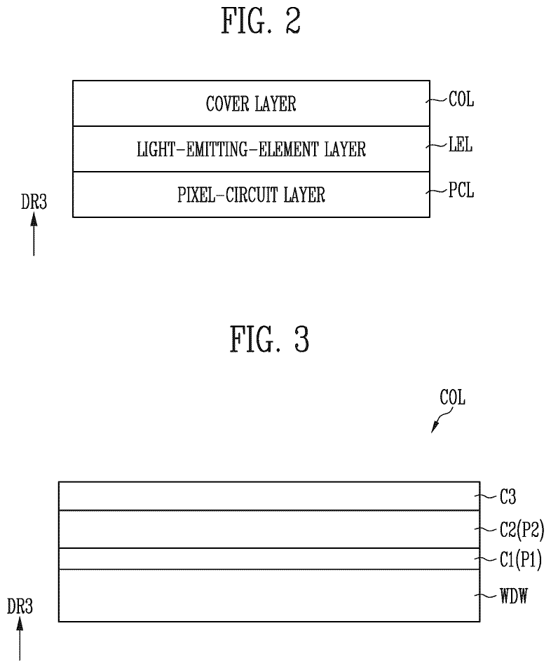

FIG. 2 is a schematic sectional view illustrating the display device DD in accordance with an embodiment.

Referring to FIG. 2, the display device DD may include a pixel-circuit layer PCL (e.g., a backplane layer), a light-emitting-element layer LEL, and a cover layer COL.

The pixel-circuit layer PCL may be a layer including a pixel circuit configured to drive the pixels PXL formed in the light-emitting-element layer LEL (or light emitting elements included in the light-emitting-element layer LEL). The pixel-circuit layer PCL may include a base layer BSL, conductive layers (e.g., electrically conductive layers) formed to form pixel circuits, and insulating layers (e.g., electrically insulating layer) on the conductive layers.

The light-emitting-element layer LEL may be on the pixel-circuit layer PCL. According to one or more embodiments, the light-emitting-element layer LEL may include the light emitting elements. According to one or more embodiments, the light emitting elements may include an organic light emitting diode (OLED). According to one or more embodiments, the light emitting elements may include an inorganic light emitting element including inorganic material. According to one or more embodiments, the light-emitting-element layer LEL may include a liquid crystal display (LCD). However, the present disclosure is not limited to the aforementioned examples.

The cover layer COL may be on the light-emitting-element layer LEL. The cover layer COL may transmit light emitted from the light-emitting-element layer LEL. The cover layer COL may have a coated structure.

Details of the cover layer COL in accordance with an embodiment will be further described below with reference to FIG. 3.

### 2. Cover Layer

FIG. 3 is a schematic sectional view illustrating the cover layer COL in accordance with an embodiment.

The cover layer COL in accordance with an embodiment is characterized in that the external light reflectance to the display device DD may be reduced, and the reflective color properties may be improved.

According to one or more embodiments, the cover layer COL may include a window layer WDW and functional layers on the window layer WDW. For example, the cover layer COL may include the window layer WDW, and a first cover layer C1, a second cover layer C2, and a third cover layer C3 on the window layer WDW.

According to one or more embodiments, the window layer WDW may form a base of the cover layer COL. According to one or more embodiments, the window layer WDW may include glass and/or a polymer. According to one or more embodiments, the window layer WDW may include polyimide as an example of the polymer, but the present disclosure is not limited thereto. According to one or more embodiments, the window layer WDW may include one or more of glass, a plastic film, and ultra-thin chemically reinforced glass (e.g., Ultra Thin Glass (UTG™)).

According to one or more embodiments, the window layer WDW may be on (e.g., directly on) an uppermost portion (e.g., a thin-film encapsulation layer and/or a capping layer) of the light-emitting-element layer LEL.

The first cover layer C1 may be on a surface of the window layer WDW. The first cover layer C1 may be in contact with the surface of the window layer WDW. The first cover layer C1 may reduce external light reflectivity of the cover layer COL.

The first cover layer C1 may include silicon oxide (SiOₓ). According to one or more embodiments, the first cover layer C1 may include silicon dioxide (SiO₂).

The first cover layer C1 may be formed through a sputtering process. According to one or more embodiments, the first cover layer C1 may include silicon oxide (SiOₓ) that is formed through a sputtering process and has a first packing density P1. According to one or more embodiments, the first cover layer C1 may include silicon dioxide (SiO₂) having the first packing density P1. According to one or more embodiments, the first cover layer C1 may be defined as a first silicon dioxide component including silicon dioxide (SiO₂) having the first packing density P1.

The packing density may be measured using the Essential Macleod program, a PerkinElmer's UV/VIS spectrophotometer (model: Lamda 1050), and an ellipsometer. For example, the packing density may be measured by comparing, using the PerkinElmer's UV/VIS spectrophotometer (model: Lambda 1050) and the 1 ellipsometer, refractive index values of material obtained while varying the packing density in the Essential Macleod program.

According to one or more embodiments, the first cover layer C1 may be formed through a sputtering process. The first cover layer C1 may include silicon oxide (SiOₓ) having a planar structure. According to one or more embodiments, as the first cover layer C1 is formed through the sputtering process, the first cover layer C1 may include silicon dioxide (SiO₂) having a planar structure.

The first cover layer C1 may have a first thickness. According to one or more embodiments, the first thickness may range from about 5 nm to about 15 nm. According to one or more embodiments, the first thickness may range from about 0.1 nm to about 9 nm. As the first cover layer C1 has a thickness in a range from about 5 nm to about 15 nm or in a range from about 0.1 nm to about 9 nm, the cover layer COL may effectively reduce external light reflectance.

According to one or more embodiments, the thickness of each of the layers disclosed in the present specification is defined based on a direction (e.g., the third direction DR3) perpendicular to a plane direction defining the plane in which the window layer WDW (or the base layer BSL) is provided.

According to one or more embodiments, the first cover layer C1 may have a refractive index in a range from about 1.43 to about 1.52. The first cover layer C1 may have a refractive index higher than the second cover layer C2 on the first cover layer C1. According to one or more embodiments, as the first cover layer C1 has a refractive index in a range from about 1.43 to about 1.52, the cover layer COL may effectively reduce external light reflectance.

According to one or more embodiments, the refractive index of each of the layers disclosed in the present specification may be defined as a refractive index for light having a wavelength of 550 nm.

The second cover layer C2 may be on one surface of the first cover layer C1. The second cover layer C2 may be in contact with the one surface of the first 1 cover layer C1. The second cover layer C2 may reduce the external light reflectivity of the cover layer COL.

The second cover layer C2 may include a same material as the first cover layer C1. According to one or more embodiments, the second cover layer C2 may include silicon oxide (SiOₓ). According to one or more embodiments, the second cover layer C2 may include silicon dioxide (SiO₂).

In the case of the cover layer COL according to the present disclosure, components between the window layer WDW and the third cover layer C3 may be formed of the same material. Accordingly, the production cost of the cover layer COL may be reduced.

The second cover layer C2 may be formed through a process different from the first cover layer C1. For example, the second cover layer C2 may be formed through an electronic-beam evaporation process. According to one or more embodiments, the second cover layer C2 may include silicon oxide (SiOₓ) that is formed by electronic-beam evaporation and has a second packing density P2. According to one or more embodiments, the second cover layer C2 may include silicon dioxide (SiO₂) having the second packing density P2. According to one or more embodiments, the second cover layer C2 may be defined as a second silicon dioxide component including silicon dioxide (SiO₂) having the second packing density P2.

As the second cover layer C2 and the first cover layer C1 are formed (or deposited) through different processes, the second packing density P2 and the first packing density P1 may differ from each other. For example, the second packing density P2 may be in a range from about 75% to about 95% of the first packing density P1.

Because the second packing density P2 and the first packing density P1 are different from each other, even if the second cover layer C2 and the first cover layer C1 include the same material, the second cover layer C2 and the first cover layer C1 may 1 have an effect similar to having a multilayer stack, thereby reducing external light reflectance.

According to one or more embodiments, the second cover layer C2 may be formed by electronic-beam evaporation. The second cover layer C2 may include silicon oxide (SiOₓ) having a columnar structure. According to one or more embodiments, as the second cover layer C2 is formed by the electronic-beam evaporation, the second cover layer C2 may include silicon dioxide (SiO₂) having a columnar structure.

Experimentally, the columnar structure may have structural reliability (e.g., structural integrity) higher than the planar structure. For example, the columnar structure may have a surface area greater than the planar structure. In embodiments, the second cover layer C2 may have a relatively large surface area, thereby leading to an increase in adhesive force with respect to a layer directly on the second cover layer C2. Accordingly, in the cover layer COL in accordance with embodiments of the present disclosure, adhesive performance of the second cover layer C2 may be increased, thereby improving the structural stability of the cover layer COL.

The second cover layer C2 may have a second thickness greater than the first cover layer C1. In the case where the first thickness ranges about 5 nm to about 15 nm, the second thickness may range from about 68 nm to about 83 nm. According to one or more embodiments, in the case where the first thickness ranges about 0.1 nm to about 9 nm, the second thickness may range from about 85 nm to about 100 nm. As the second cover layer C2 has a thickness in a range from about 68 nm to about 83 nm or in range from about 85 nm to about 100 nm, the cover layer COL may effectively reduce the external light reflectance.

The second cover layer C2 may have a refractive index lower than the first cover layer C1. For example, the second cover layer C2 may have a refractive index in a range from about 1.32 to about 1.52.

1 As the second cover layer C2 is formed through a process different from that of the first cover layer C1, the second cover layer C2 may have a refractive index different from that of the first cover layer C1, so that the cover layer COL may have a graded refractive index. For example, the second cover layer C2 may have a refractive index lower than that of the first cover layer C1, and the cover layer COL may effectively reduce the external light reflectance.

Furthermore, in the cover layer COL in accordance with embodiments of the present disclosure, the first cover layer C1 and the second cover layer C2 including a single material may be in contact between the third cover layer C3 and the window layer WDW. Accordingly, residual stress between the stacked components in the cover layer COL may be reduced, and adhesive force between the stacked components in the cover layer COL may be enhanced.

The third cover layer C3 may be on a surface of the second cover layer C2. The third cover layer C3 may be in contact with the surface of the second cover layer C2. The third cover layer C3 may be on a surface of the cover layer COL, suppressing or reducing abrasion of the surface.

The third cover layer C3 may include a material for implementing an anti-reflection function. For example, the third cover layer C3 may include perfluorinated polyether (PFPE). PFPE may be formed of rigid and short perfluoroalkyl chains having highly flexible ether linkages introduced. Therefore, the third cover layer C3 may have smooth amorphous characteristics, excellent fingerprint resistance, and excellent slip characteristics.

The third cover layer C3 may be formed by thermal evaporation and/or electronic-beam evaporation.

The third cover layer C3 may have a thickness in a range from about 20 nm to about 30 nm. However, the present disclosure is not limited to the foregoing. The thickness of the third cover layer C3 may be optimized or improved in relation to the other layers forming the cover layer COL, thereby maximizing or increasing technical 1 effects of securing the fingerprint resistance, reducing external light reflectance, and improving reflective color properties.

According to one or more embodiments, the cover layer COL may have an average transmittance of 92% or more for light having a wavelength of approximately 550 nm when measured using a PerkinElmer's UV/VIS spectrophotometer (model: Lamda 1050). According to one or more embodiments, the cover layer COL may have an average transmittance of 92% or more for light having a wavelength in a range from about 400 nm to about 700 nm when measured using a PerkinElmer's UV/VIS spectrophotometer (model: Lamda 1050).

According to one or more embodiments, the cover layer COL may have an average reflectivity of 7% or less for light having a wavelength of approximately 550 nm when measured using a PerkinElmer's UV/VIS spectrophotometer (model: Lamda 1050). According to one or more embodiments, the cover layer COL may have an average reflectivity of 7% or less for light having a wavelength in a range from 400 nm to 700 nm when measured using a PerkinElmer's UV/VIS spectrophotometer (model: Lamda 1050).

According to one or more embodiments, the cover layer COL may have a color difference (or color shift) of 2 or less when measured using a Minolta's spectrophotometer (model: CM-3700A).

Hereinafter, the subject matter of the present disclosure will be described in more detail based on embodiments and comparative examples. Here, the following embodiments and comparative examples are provided merely for further detailed explanation of the present disclosure, and the present disclosure is not limited to the embodiments and comparative examples.

### 3. Embodiment and Comparative Example

### (1) Fabrication example—Embodiment and Comparative Example

### Embodiment

The first cover layer C1 including silicon dioxide (SiO₂) was stacked on the window layer WDW that was a glass substrate having a thickness of 0.5 mm by sputtering, and the second cover layer C2 including silicon dioxide (SiO₂) and the third cover layer C3 including PFPE were sequentially stacked on the first cover layer C1 by electronic-beam evaporation, thereby fabricating the cover layer COL in accordance with embodiments of the present disclosure.

In the cover layer COL in accordance with the embodiment, the first cover layer C1 was formed to have a thickness of 10 nm, the second cover layer C2 was formed to have a thickness of 75 nm, and the third cover layer C3 was formed to have a thickness of 25 nm.

### Comparative Example 1

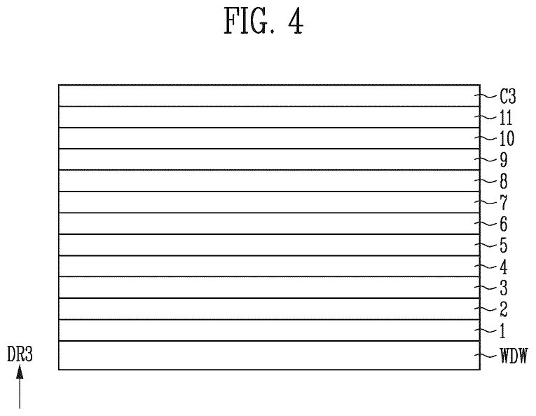

Comparative example 1 was fabricated as a comparative example for comparison of color shift characteristics. A schematic structure of comparative example 1 is illustrated in FIG. 4. FIG. 4 is a schematic cross-sectional view of comparative example 1.

Comparative example 1 was fabricated by sequentially stacking a first layer 1, a second layer 2, a third layer 3, a fourth layer 4, a fifth layer 5, a sixth layer 6, a seventh layer 7, an eighth layer 8, a ninth layer 9, a tenth layer 10, an eleventh layer 11, and the third cover layer C3 on the window layer WDW that was a glass substrate having a thickness of 0.5 mm.

The first layer 1, the third layer 3, the fifth layer 5, the seventh layer 7, and the ninth layer 9 each included silicon nitride (Si₃N₄). The second layer 2, the fourth layer 4, the sixth layer 6, the eighth layer 8, the tenth layer 10, and the eleventh layer 11 each included silicon dioxide (SiO₂).

Here, the tenth layer 10 was deposited by sputtering and formed to have a thickness of 68.7 nm. The eleventh layer 11 was deposited by electronic-beam evaporation and formed to have a thickness of 10 nm.

The third cover layer C3 was formed by the same processing method as the embodiment to have the same thickness.

In addition, the first to ninth layers 1 to 9 were formed to have thicknesses of 10 nm, 415 nm, 30 nm, 17.9 nm, 271 nm, 11.69 nm, 45.58 nm, 19.18 nm, and 142.48 nm, respectively.

### Comparative Example 2

As a comparative example for comparing reflectance and transmittance characteristics, a glass substrate having a thickness of 0.5 mm was used as a bare glass substrate in which the first cover layer C1, the second cover layer C2, and the third cover layer C3 were not formed.

### (2) Experimental Example

### [Experimental Example 1]—Measurement of Color Shift Characteristics

An experiment was performed to measure color shift (E) of the cover layers fabricated according to the embodiment and comparative example 1.

In the present experiment, an International Commission on Illumination (CIE) illuminant selected from the group consisting of an A-series illuminant, a B-series illuminant, a C-series illuminant, a D-series illuminant, and an F-series illuminant was used. Based on each of the cover layers, a color coordinate position of light recognized when light emitted from the illuminant was normally incident on each of the cover layers was set as a reference position. The color coordinate position was determined when light emitted from the illuminant was incident at an incident illumination angle in a range from 0° to 60° on each of the cover layers. Color shift data was determined based on each determined color coordinate position. The color shift may be represented by a numeral value determined based on the reference position, and may refer to a difference between determined color coordinates and color coordinates of the reference position. Equipment used in the present experiment may be a Minolta's spectrophotometer (model: CM-3700A).

TABLE 1

| | Color coordinates when | |
|---|---|---|
| | light from illuminator is incident at | Color |
| Classification | incident illumination angle | shift(E) |
| Embodiment | (0.2, 0.55) | 0.58 |
| Comparative | (−1.0, −1.38) | 1.70 |
| Example | | |

Referring to Table 1, it can be seen that the color shift characteristics of the cover layer COL in accordance with the embodiment are significantly superior compared to those of the comparative example. In accordance with the cover layer COL according to the embodiment, there may be provided the display device DD that is excellent in display quality according to a viewing angle.

### [Experimental Example 2]—Measurement of Transmittance

An experiment was performed to measure transmittance characteristics of the cover layer COL fabricated according to the embodiment. In order to verify the transmittance improvement effect of the cover layer COL fabricated according to the embodiment, the same experiment was performed using a bare glass substrate in which some components of the cover layer COL were not provided according to comparative example 2.

In the present experiment, light having a wavelength of approximately 550 nm was applied to the cover layer COL and the bare glass substrate of comparative example 2, and the intensity of transmitted light was measured. As a result, the ratio of the intensity of the transmitted light to the intensity of the applied light was calculated. Equipment used in the present experiment may be a PerkinElmer's UV/VIS spectrophotometer (model: Lambda 1050).

TABLE 2

| Classification | Transmittance(%) |
|---|---|
| Embodiment | 92.5 |
| Comparative example 2 | 91.5 |

Referring to Table 2, it can be seen that the cover layer COL according to the embodiment has excellent transmittance characteristics compared to comparative example 2.

### [Experimental Example 3]—Measurement of Reflectance

An experiment was performed to measure reflectance characteristics of the cover layer COL fabricated according to the embodiment. In order to verify the reflectance reduction effect of the cover layer COL fabricated according to the embodiment, the same experiment was performed using a bare glass substrate in which some components of the cover layer COL were not provided according to comparative example 2.

In the present experiment, light having a wavelength of approximately 550 nm was applied to the cover layer COL and the bare glass substrate of comparative example 2, and the intensity of reflected light was measured. As a result, the ratio of the intensity of the reflected light to the intensity of the applied light was calculated. Equipment used in the present experiment may be a PerkinElmer's UV/VIS spectrophotometer (model: Lambda 1050).

TABLE 3

| Classification | Reflectance (%) |
|---|---|
| Embodiment | 6.95 |
| Comparative example 2 | 8.2 |

Referring to Table 3, it can be seen that the cover layer COL according to the embodiment has excellent reflectance characteristics compared to comparative example 2. In summary, according to an embodiment, it is possible to implement the display device DD having improved transmittance characteristics and reflectance characteristics and markedly improved color deviation (or color shift) characteristics.

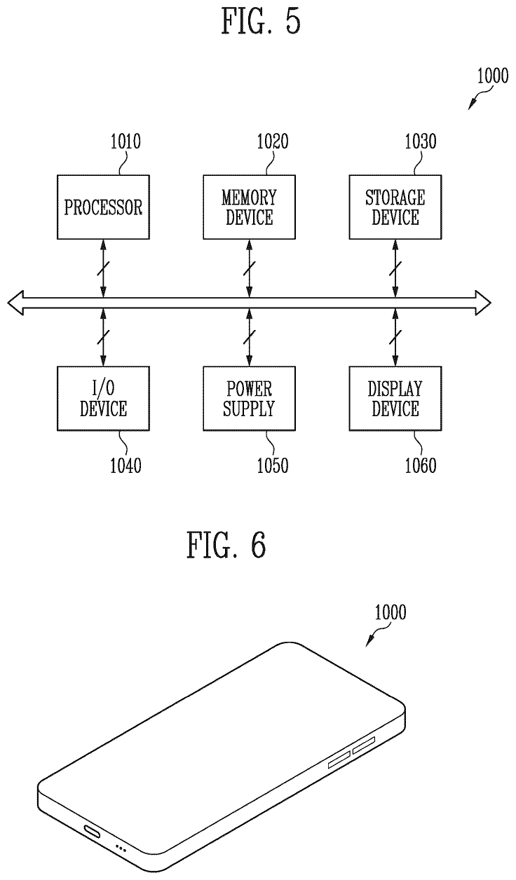

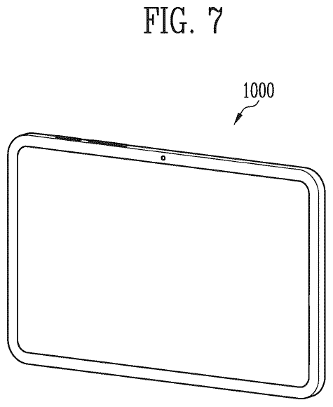

FIG. 5 is a schematic block diagram illustrating an electronic device 1000 including a display device in accordance with an embodiment. FIG. 6 is a schematic diagram illustrating an example where the electronic device 1000 of FIG. 5 is a smartphone. FIG. 7 is a schematic diagram illustrating an example where the electronic device 1000 of FIG. 5 is a tablet computer.

Referring to FIGS. 5 to 7, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 6, the electronic device 1000 may be a smartphone. In an embodiment, as illustrated in FIG. 7, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

Various embodiments of the present disclosure may provide a cover layer for display devices having improved visibility by controlling external light reflectance, and a display device including the cover layer.

Various embodiments of the present disclosure may provide a cover layer for display devices having improved reliability in display quality achieved by excellent reflective color properties, and a display device including the cover layer.

Various embodiments of the present disclosure are directed to a cover layer for display devices capable of reducing the cost of producing a display device, and a display device including the cover layer.

While various example embodiments have been described above, those having ordinary skill in the art will appreciate that various modifications, additions and substitutions are possible, without departing from the scope and spirit of the present disclosure.

Therefore, the embodiments disclosed in this specification are only for illustrative purposes rather than limiting the technical spirit of the present disclosure. The scope of the present disclosure must be defined by the accompanying claims, and equivalents thereof.

What is claimed is:

1. A cover layer for display devices, comprising:
a window layer;
a first cover layer on the window layer; and
a second cover layer on the first cover layer,
wherein the first cover layer comprises silicon oxide having a first packing density,
wherein the second cover layer comprises silicon oxide having a second packing density different from the first packing density, and
wherein the first cover layer and the second cover layer are in contact with each other.

2. The cover layer according to claim 1, wherein the second packing density is in a range from about 75% to about 95% of the first packing density.

3. The cover layer according to claim 1, wherein the silicon oxide of the first cover layer comprises silicon dioxide, and the silicon oxide of the second cover layer comprises silicon dioxide.

4. The cover layer according to claim 3,
wherein the silicon dioxide of the first cover layer has a planar structure, and
wherein the silicon dioxide of the second cover layer has a columnar structure.

5. The cover layer according to claim 1,
wherein the first cover layer is formed through a sputtering process, and
wherein the second cover layer is formed through an electronic-beam evaporation process.

6. The cover layer according to claim 1,
wherein the first cover layer has a first thickness,
wherein the second cover layer has a second thickness,
wherein the first thickness ranges from about 5 nm to about 15 nm or ranges from about 0.1 nm to about 9 nm, and
wherein the second thickness ranges from about 68 nm to about 83 nm or ranges from about 85 nm to about 100 nm.

7. The cover layer according to claim 1,
wherein the first cover layer has a refractive index in a range from 1.43 to 1.52, and
wherein the second cover layer has a refractive index in a range from 1.32 to 1.52.

8. The cover layer according to claim 1, further comprising a third cover layer on the second cover layer,
wherein the second cover layer and the third cover layer are in contact with each other.

9. The cover layer according to claim 8, wherein the third cover layer is formed through thermal evaporation or electronic-beam evaporation.

10. The cover layer according to claim 8, wherein the third cover layer comprises perfluorinated polyether.

11. The cover layer according to claim 8, wherein the third cover layer has a thickness in a range from about 20 nm to about 30 nm.

12. A cover layer for display devices, comprising:
a window layer;
a first cover layer on the window layer, and having a first packing density and a first thickness; and
a second cover layer directly on the first cover layer, and having a second packing density and a second thickness,
wherein the first cover layer and the second cover layer comprise an identical material,
wherein the first packing density and the second packing density differ from each other, and
wherein the second thickness is greater than the first thickness.

13. The cover layer according to claim 12,
wherein the first cover layer is formed through a sputtering process, and
wherein the second cover layer is formed through an electronic-beam evaporation process.

14. The cover layer according to claim 13,
wherein the identical material of the first cover layer and the second cover layer comprises silicon dioxide (SiO₂),
wherein the second packing density is in a range from about 75% to about 95% of the first packing density,
wherein the silicon dioxide of the first cover layer has a planar structure, and
wherein the silicon dioxide of the second cover layer has a columnar structure.

15. The cover layer according to claim 14, wherein the first cover layer has a higher refractive index than the second cover layer.

16. A display device, comprising:
a light-emitting-element layer comprising a light emitting element configured to emit light; and
a cover layer on the light-emitting-element layer,
wherein the cover layer comprises:
a window layer;
a first cover layer on the window layer; and
a second cover layer on the first cover layer,
wherein the first cover layer comprises silicon oxide (SiOₓ) having a first packing density,
wherein the second cover layer comprises silicon oxide having a second packing density different from the first packing density, and
wherein the first cover layer and the second cover layer are in contact with each other.

17. The display device according to claim 16, wherein the first cover layer is formed through a process different from a process of forming the second cover layer.

18. The display device according to claim 16,
wherein the first cover layer has a first thickness,
wherein the second cover layer has a second thickness,
wherein the first thickness ranges from about 5 nm to about 15 nm or ranges from about 0.1 nm to about 9 nm, and
wherein the second thickness ranges from about 68 nm to about 83 nm or ranges from about 85 nm to about 100 nm.

19. The display device according to claim 16,
wherein the first cover layer has a refractive index in a range from about 1.43 to about 1.52, and
wherein the second cover layer has a refractive index in a range from about 1.32 to about 1.52.

20. The display device according to claim 16, further comprising a third cover layer on the second cover layer,
wherein the second cover layer and the third cover layer are in contact with each other, and
wherein the third cover layer has a thickness in a range from about 20 nm to about 30 nm.

21. An electronic device, comprising:
a processor to provide input image data; and
a display device to display an image based on the input image data,
wherein the display device comprises: a light-emitting-element layer comprising a light emitting element configured to emit light; and a cover layer on the light-emitting-element layer,
wherein the cover layer comprises:
a window layer;
a first cover layer on the window layer; and
a second cover layer on the first cover layer,
wherein the first cover layer comprises silicon oxide (SiOₓ) having a first packing density,
wherein the second cover layer comprises silicon oxide having a second packing density different from the first packing density, and
wherein the first cover layer and the second cover layer are in contact with each other.
